(19) United States
(12) Patent Application Publication
(10) Pub. No.: US 2026/0059833 A1
(43) Pub. Date: Feb. 26, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Wen Chieh HO, Hsinchu County (TW); Kaochao CHEN, Hsinchu City (TW); Chia-Cheng HO, Hsinchu City (TW); Chan-yu HUNG, Tainan City (TW)

(21) Appl. No.: 18/815,557

(22) Filed: Aug. 26, 2024

(51) Int. Cl. H01L 29/40; H01L 29/66; H01L 29/78

(52) U.S. Cl. CPC H10D 64/111; H10D 30/0281; H10D 30/65; H10D 64/01

(57) ABSTRACT

A high-voltage transistor includes a hybrid field plate structure in a channel region of the high-voltage transistor that is between a gate structure and a source/drain region of the high-voltage transistor. The hybrid field plate structure includes a multiple-layer structure in which a plurality of layers (e.g., a bottom layer and a top layer, among other examples) that contain different materials are stacked above the channel region. The different materials of the layers of the hybrid field plate structure enable the bottom layer to be etched at a faster etch rate than the top layer. The faster etch rate enables the ends of the bottom layer to be etched such that the ends of the top layer overhang laterally outward past the bottom layer. This overhang creates a buffer region under the ends of the top layer.

### BACKGROUND

A high-voltage transistor is a type of metal oxide semiconductor (MOS) transistor that may be configured to operate at a higher drain voltage relative to a low voltage transistor. Low voltage transistors may be used in applications such as logic circuits (e.g., processors), memory (e.g., static random access memory (SRAM)), and/or input/output (I/O) circuits, among other examples. High-voltage transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIG. 2 is a diagram of an example implementation of an integrated circuit device described herein.

FIG. 3 is a diagram of an example of electron potential in an integrated circuit device that includes a hybrid field plate structure described herein.

FIGS. 4A-4L are diagrams of an example implementation of forming an integrated circuit device that includes a hybrid field plate structure described herein.

FIG. 5 is a diagram of an example implementation of an integrated circuit device described herein.

FIGS. 6A and 6B are diagrams of an example implementation of an integrated circuit device described herein.

FIG. 7 is a flowchart of an example process associated with forming an integrated circuit device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To operate at higher drain voltages, a high-voltage transistor may be manufactured to withstand a high breakdown voltage. Breakdown voltage is a voltage at or near which a transistor ceases to operate according to the intended operating principles of the transistor. In a high-voltage transistor, gate-to-drain voltages may sometimes satisfy or exceed the breakdown voltage of the high-voltage transistor due to the high drain voltages experienced by the high-voltage transistor.

In some cases, a distance between a gate structure and a drain region of a high-voltage transistor may be increased to increase the breakdown voltage (BV) of the high-voltage transistor. Increasing the distance between the gate structure and the drain region provides for greater distribution of an electric field between the gate structure and the drain region, which reduces the peak magnitude of the electric field (thereby increasing the breakdown voltage).

However, increasing the distance between the gate structure and the drain region increases the footprint of the high-voltage transistor. The increased footprint may reduce the operating efficiency of the high-voltage transistor, may increase resistance in the high-voltage transistor, and/or may result in reduced density of high-voltage transistors in a semiconductor device, among other examples.

In some implementations described herein, a high-voltage transistor includes a hybrid field plate structure above a channel region of the high-voltage transistor that is between a gate structure and a source/drain region of the high-voltage transistor. The hybrid field plate structure includes a multiple-layer structure in which a plurality of layers (e.g., a bottom layer and a top layer, among other examples) that contain different materials are stacked above the channel region. The different materials of the layers of the hybrid field plate structure enable the bottom layer to be etched at a faster etch rate than the top layer. The faster etch rate enables the ends of the bottom layer to be etched such that the ends of the top layer overhang laterally outward past the bottom layer. This overhang creates a buffer region under the ends of the top layer.

The hybrid field plate structure may increase the performance of the high-voltage transistor by controlling the electric field generated in the channel region of the high-voltage transistor. In particular, an electrical bias (e.g., a voltage, a current) may be applied to the hybrid field plate structure, which enables the hybrid field plate structure to suppress the reducing peak electric field magnitude of the electric field through the reduced surface field (RESURF) effect. Here, the hybrid field plate structure reduces the peak electric field magnitude of the electric field by distributing the electric field across a greater area, and the greater electric field distribution provides for a higher breakdown voltage for the high-voltage transistor.

The buffer region under the ends of the top layer of the hybrid field plate structure provides for further electric field distribution in that the buffer region provides additional area across which the electric field can be distributed for further reduction in the peak electric field magnitude of the electric field. Thus, the buffer region increases the performance of the high-voltage transistor with minimal to no increase in lateral footprint of the high-voltage transistor.

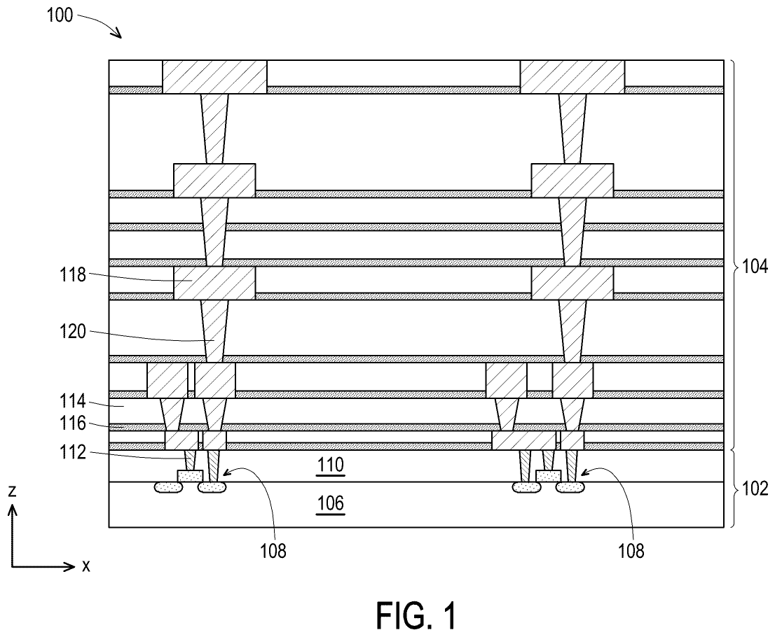

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or a front end of line (FEOL) region of the semiconductor device 100. The interconnect layer 104 may also be referred to as a backend region or a back end of line (BEOL) region of the semiconductor device 100.

The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Integrated circuit devices 108 may be included in and/or on the substrate 106 in the device layer 102 of the semiconductor device 100. The integrated circuit devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

In some implementations, one or more of the integrated circuit devices 108 include a high-voltage transistor (or a medium voltage transistor). “High-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure.

A high-voltage transistor (or a medium voltage transistor) may include a laterally diffused (or laterally double diffused) metal-oxide semiconductor (LDMOS) transistor that has a drift region in which charge carriers are laterally diffused to facilitate distribution of an electric field between a gate structure and a source/drain region of the high-voltage transistor. The lateral diffusion of charge carriers in the drift region enables the high-voltage transistor to withstand higher gate and source/drain voltages (e.g., by increasing the breakdown voltage of the high-voltage transistor) than low voltage transistors.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the integrated circuit devices 108 in the z-direction in the semiconductor device 100. The integrated circuit devices 108 may be electrically coupled to the interconnect layer 104 by contact structures 112. In some implementations, an integrated circuit device 108 may be electrically coupled to gate contacts and source/drain contacts. The contact structures 112 may include contact plugs, vias, pillars, contact pads, and/or another type of electrically conductive contacts. The contact structures 112 may include one or more electrically conductive materials such as tungsten (W), cobalt (Co), ruthenium (Ru), titanium (Ti), an alloy thereof, a metal nitride that contains one or more metals, and/or another electrically conductive material. In some implementations, a liner is included between a contact structure 112 and the dielectric layer 110. The liner may include an adhesion liner, a barrier liner, and/or another type of liner, and may include liner materials such as tantalum (Ta), tantalum nitride (TaN), and/or titanium nitride (TiN), among other examples.

The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104.

The interconnect layer 104 includes a plurality of conductive structures. One or more of the conductive structures are electrically coupled and/or physically coupled with one or more of the integrated circuit devices 108 (e.g., with the contact structures 112 of the integrated circuit devices 108) in the device layer 102. The conductive structures provide electrical routing that enables signals and/or power to be provided to and/or from the integrated circuit devices 108. The conductive structures may include a combination of metallization structures 118 and interconnect structures 120. The metallization structures 118 may include trenches, metallization layers, conductive traces, and/or other types of metallization structures. The interconnect structures 120 may include vias, plugs, interconnects, and/or another type interconnect structures. The metallization structures 118 and the interconnect structures 120 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the metallization structures 118 and the interconnect structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 118 and the interconnect structures 120 of the interconnect layer 104 may be arranged in in a vertical manner (e.g., in the z-direction). In other words, a plurality of stacked metallization structures 118 and interconnect structures 120 extend between the device layer 102 and a top of the interconnect layer 104 to facilitate electrical signals and/or power to be routed between the device layer 102 and connection structures (not shown) of the semiconductor device 100. The plurality of stacked metallization structures 118 may be arranged in layers referred to as M-layers. For example, a metal-0 (M0) layer may located at the bottom of the interconnect layer 104 and may be directly coupled with the device layer 102 (e.g., with the contact structures 112 of the integrated circuit devices 108 in the device layer 102). A via-1 (V1) layer that includes one or more interconnect structures 120 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on. Additionally, via layers may be included between vertically arranged M-layers.

As indicated above, FIG. 1 is provided as an example. Other examples may differ from what is described with regard to FIG. 1.

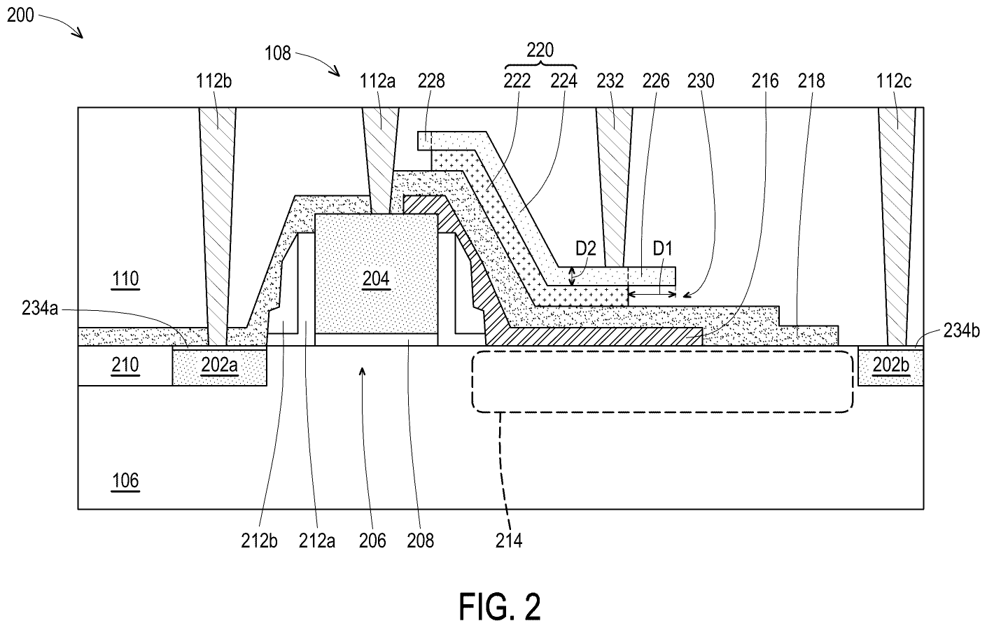

FIG. 2 is a diagram of an example implementation 200 of an integrated circuit device 108 described herein. In the example implementation 200, the integrated circuit device 108 includes a high voltage transistor such as an LDMOS transistor.

As shown in FIG. 2, the integrated circuit device 108 may include (or may be included on) the substrate 106 of the semiconductor device 100. The integrated circuit device 108 may include a source/drain region 202a in the substrate 106, a source/drain region 202b in the substrate 106, and a gate structure 204 on the substrate 106. A source/drain region may refer to a source region, a drain region, or a combination of a source and drain region, depending on the context. In some implementations, the source/drain region 202a is a source region of the integrated circuit device 108 and the source/drain region 202b is a drain region of the integrated circuit device 108 that is configured to operate at a relatively high voltage such as up to approximately 36 volts.

The gate structure 204 may be located laterally between the source/drain regions 202a and 202b. The source/drain region 202a may be located on a first side (e.g., laterally adjacent to the first side) of the gate structure 204, and the source/drain region 202b may be located on a second side (e.g., laterally adjacent to the second side) of the gate structure 204 opposing the first side. The source/drain regions 202a and 202b may each include one or more doped regions of the substrate 106. In some implementations, the source/drain regions 202a and 202b may include the same dopant type. For example, the source/drain regions 202a and 202b may each include silicon doped with one or more p-type dopants such as boron (B) and/or gallium (Ga), among other examples. As another example, the source/drain regions 202a and 202b may each include silicon doped with one or more n-type dopants such as arsenic (A) and/or phosphorous (P), among other examples. In some implementations, the source/drain regions 202a and 202b include different dopant types. For example, the source/drain region 202a may include silicon doped with one or more p-type dopants, and the source/drain region 202b may include silicon doped with one or more n-type dopants.

In some implementations, the gate structure 204 includes a polysilicon gate. In some implementations, the gate structure 204 includes a metal gate and includes one or more metal materials such as tungsten (W), titanium (Ti), titanium aluminum (TiAl), and/or other suitable metal materials.

A region of the substrate 106 between the source/drain region 202a and the source/drain region 202b may be referred to as a channel region (or active region) 206 of the integrated circuit device 108. The channel region 206 includes one or more semiconductor materials such that the conductivity of the channel region 206 that may be selectively controlled using an electric field. In this way, an electrical current may selectively flow between the source/drain region 202a and the source/drain region 202b based the electrical conductivity of the channel region 206. A voltage may be selectively applied to the gate structure 204 to selectively control the conductivity of the channel region 206 in the substrate 106.

A gate dielectric layer 208 may be included on the substrate 106 between the substrate 106 and the gate structure 204. The gate dielectric layer 208 may provide electrical isolation between the gate structure 204 and the substrate 106, which enables a voltage applied to the gate structure 204 to cause an electric field to be generated in the substrate 106. In some implementations, the gate dielectric layer 208 may include a low dielectric constant (low-k) dielectric material such as a silicon oxide (SiOₓ such as SiO₂). Additionally and/or alternatively, the gate dielectric layer 208 may include a high dielectric constant (high-k) dielectric material (e.g., a dielectric material having a dielectric constant that is greater than approximately 3.9) such as a silicon nitride (SiₓN_{y} such as Si₃N₄), a hafnium oxide (HfOₓ such as HfO₂), and/or aluminum oxide (AlₓO_{y} such as Al₂O₃), among other examples.

One or more isolation regions (e.g., shallow trench isolation (STI) regions) 210 may be included in the substrate 106. The one or more isolation regions 210 may electrically isolate active regions of adjacent integrated circuit devices 108. The one or more isolation regions 210 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The one or more isolation regions 210 may include a multi-layer structure, for example, having one or more liner layers.

One or more sidewall spacer layers may be included over and/or on sidewalls of the gate structure 204. For example, seal spacer layers 212a may be included on the sidewalls of the gate structure 204. The seal spacer layers 212a may be conformally deposited and may include a silicon oxycarbide (SiOC), a nitrogen free SiOC, or another suitable material. As another example, bulk spacer layers 212b may be included on the seal spacer layers 212a. The bulk spacer layers 212b may be formed of similar materials as the seal spacer layers 212a. The bulk spacer layers 212b may be formed to a greater thickness relative to the thickness of the seal spacer layers 212a.

As shown in FIG. 2, a drain extension region 214 may correspond to a portion of the channel region 206 between the gate structure 204 and the source/drain region 202b. During operation of the integrated circuit device 108, a depletion region may be formed in the drain extension region 214. In the depletion region, the magnitude (or intensity) of an electric field formed in the channel region 206 is non-uniform between the gate structure 204 and the source/drain region 202b. The magnitude of the electric field in the depletion region may be highest near the gate structure 204, and may decrease from the gate structure 204 to the source/drain region 202b. If the magnitude of the electric field near the gate structure 204 reaches the critical breakdown field of the integrated circuit device 108 (e.g., the maximum electric field at breakdown), the breakdown voltage of the integrated circuit device 108 may be exceeded.

To suppress the peak magnitude of the electric field in the drain extension region 214 so as to achieve a higher breakdown voltage for the integrated circuit device 108, a layer stack is included above the drain extension region 214. The layer stack includes a combination of layers that is configured to more evenly distribute the magnitude of the electric field across the drain extension region 214, which reduces the peak magnitude of the electric field in the integrated circuit device 108. The layer stack may include a blocking layer 216 on the substrate, a buffer layer 218 on the blocking layer 216, and a hybrid field plate structure 220 on the buffer layer 218.

The blocking layer 216 may include a resist-protection oxide (RPO) layer configured to prevent silicide formation on the substrate 106, on the gate structure 214, and/or on surfaces of the integrated circuit device 108 other than on the source/drain region 202b. The buffer layer 218 provides a vertical buffer for the hybrid field plate structure 220 and enables the electric field to be further distributed across a greater area for electric field distribution tuning.

The blocking layer 216 and the buffer layer 218 may extend along a side of the gate structure 204 and along the substrate 106 between the gate structure 204 and the source/drain region 202b. The buffer layer 218 may be included on both sides of the gate structure 204. In some implementations, the blocking layer 216 may continuously extend along the substrate 106 between the gate structure 204 and the source/drain region 202b. In some implementations, the blocking layer 216 extends over a portion of the surface of the substrate 106 between the gate structure 204, and the buffer layer 218 extends over the remaining portion of the surface of the substrate 106 between the gate structure 204. The source/drain regions 202a and 202b are exposed through the blocking layer 216 to enable a metal silicide layers to be formed on the source/drain regions 202a and 202b. The blocking layer 216 and the buffer layer 218 may each include one or more dielectric materials, such as an oxide (e.g., SiOₓ such as SiO₂), a nitride (e.g., SiₓN_{y} such as Si₃N₄), a carbide, an oxynitride, an oxycarbide, and a nitride carbide, a polymer, the like, and/or another suitable dielectric material.

The hybrid field plate structure 220 may extend along the side of the gate structure 204 facing the source/drain region 202b and along a portion of the blocking layer 216 and a portion of the buffer layer 218 above the drain extension region 214 in the substrate 106. The hybrid field plate structure 220 includes a multiple-layer structure that includes a bottom layer 222 on the buffer layer 218 and a top layer 224 on the bottom layer 222. In some implementations, the hybrid field plate structure 220 includes additional layers.

The hybrid field plate structure 220 may be a “hybrid” structure in that the bottom layer 222 and the top layer 224 include different material compositions. The bottom layer 222 may include a metal such as copper (Cu), gold (Au), silver (Ag), nickel (Ni), tin (Sn), tantalum (Ta), ruthenium (Ru), cobalt (Co), tungsten (W), titanium (Ti), and/or another metal. The top layer 224 may include a metal nitride material (e.g., titanium nitride (TiN), tungsten nitride (WN), tantalum nitride (TaN), a metal oxide (e.g., titanium oxide (TiO₂)), and/or another type of metal-containing material. In some implementations, the top layer 224 includes a nitride of the metal of the bottom layer 222. For example, the bottom layer 222 may include titanium (Ti), and the top layer 224 may include titanium nitride (TiN). As another example, the bottom layer 222 may include tantalum (Ta), and the top layer 224 may include tantalum nitride (TaN).

The different materials of the bottom layer 222 and the top layer 224 provide different etch rates for the bottom layer 222 and the top layer 224 when etched with the same etchant. The different etch rates enable the bottom layer 222 to be laterally etched with minimal to no lateral etching of the top layer 224. This enables top layer 224 to laterally overhang the ends of the bottom layer 222. For example, an extension segment 226 of the top layer 224 may extend laterally outward past an end of the bottom layer 222 that is facing the source/drain region 202b. Thus, the end of the top layer 224 facing the source/drain region 202b is closer to the source/drain region 202b than the end of the bottom layer 222 facing the source/drain region 202b. As another example, an extension segment 228 of the top layer 224 may extend laterally outward past an end of the bottom layer 222 that is facing the gate structure 204.

The overhang of the extension segment 226 provides an area under the top layer 224 that can be filled in with dielectric material (e.g., from the dielectric layer 110 and/or from another dielectric layer). This area under the top layer 224 is a buffer region 230 into which the electric field of the integrated circuit device 108 may extend. Thus, the buffer region 230 increases the area across which the electric field can be distributed. The breakdown voltage of the integrated circuit device 108 may correspond to an integral of the area across which the electric field is distributed. The greater the distribution area of the electric field, the higher the breakdown voltage that can be sustained by the integrated circuit device 108. Thus, the increased distribution area provided by the buffer region 230 increases the breakdown voltage of the integrated circuit device 108, which enables the source/drain region 202b to be operated at higher operating voltages without sustaining a breakdown of the integrated circuit device 108.

In some implementations, a length (indicated in FIG. 2 as a dimension D1) of the overhang of the extension segment 226 over the end of the bottom layer 222 may be greater than 0 nanometers and less than approximately 500 nm nanometers to provide a sufficient increase in electric field distribution area while maintaining sufficient control of the peak electric field distribution grading. However, other ranges and values for the length of the overhang of the extension segment 226 over the end of the bottom layer 222 are within the scope of the present disclosure. In some implementations, a thickness (indicated in FIG. 2 as a dimension D2) of the top layer 224 of the hybrid field plate structure 220 is included in a range of approximately 50 angstroms to approximately 1000 angstroms. However, other values and ranges for the thickness of the top layer 224 are within the scope of the present disclosure.

As further shown in FIG. 2, the dielectric layer 110 may be included over the integrated circuit device 108. The field plate contact 232 may extend through the dielectric layer 110. Additionally, a contact structure 112a (e.g., a gate contact) may be included in the one or more dielectric layers and may be electrically connected and/or physically connected with the gate structure 204, and contact structures 112b and 112c (e.g., source/drain contacts) may be included in the dielectric layer 110 and may be electrically connected and/or physically connected with the source/drain regions 202a and 202b, respectively.

A bias voltage may be applied to the hybrid field plate structure 220 through the field plate contact 232 to reduce the peak electric field in the drain extension region 214. The bias voltage increases carrier depletion in the drain extension region 214, thereby reducing the peak electric field strength in the drain extension region 214. By manipulating the electric field, the integrated circuit device 108 can achieve increased breakdown voltages.

As further shown in FIG. 2, metal silicide layers 234a and 234b may be included on the source/drain regions 202a and 202b of the integrated circuit device 108, respectively. The metal silicide layers 234a and 234b may each include a titanium silicide (TiSi), a ruthenium silicide (RuSi), and/or another type of metal silicide material. The metal silicide layers 234a and 234b provide a transition between the semiconductor material of the source/drain regions 202a and 202b and metal material of the contact structures 112b and 112c that are respectively formed on the source/drain regions 202a and 202b. The metal silicide layers 234a and 234b enable a low contact resistance to be achieved between the contact structures 112b, 112c and the source/drain regions 202a, 202b.

In this way, the integrated circuit device 108 includes a hybrid field plate structure 220 that extends along a portion of the buffer layer 218. The hybrid field plate structure includes a bottom layer 222 on the buffer layer 218 and a top layer 224 on the bottom layer 222. The bottom layer includes a first material, and the top layer 224 includes a second material that is different from the first material. The top layer 224 includes an extension segment 226 that extends laterally outward past an end of the bottom layer 222. The extension segment 226 extends laterally toward the source/drain region 202b. The top layer 224 may include another extension segment 228 that extends laterally outward past another end of the bottom layer 222 facing the gate structure 204. The other extension segment 228 may extend over a portion of the gate structure 204. The end of the bottom layer 222 facing the source/drain region 202b is further away from the source/drain region 202b than the end of the top layer 224 facing the second source/drain region 202b. A dielectric buffer region 230 may be included vertically between the buffer layer 218 and the top layer 224 of the hybrid field plate structure 220. The dielectric buffer region 230 may be laterally adjacent to the end of the bottom layer 222 that is facing the source/drain region 202b. The end of the bottom layer 222 facing the gate structure 204 may be located further away from the gate structure 204 than the end of the top layer 224 facing the gate structure 204.

As indicated above, FIG. 2 is provided as an example. Other examples may differ from what is described with regard to FIG. 2.

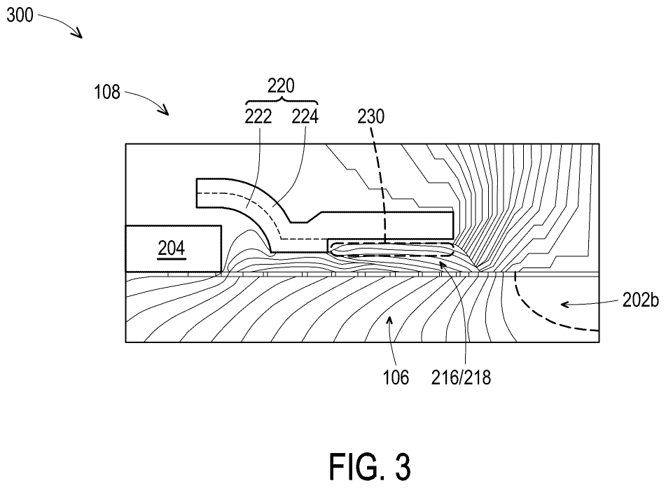

FIG. 3 is a diagram of an example 300 of electron potential in an integrated circuit device 108 that includes a hybrid field plate structure 220 described herein. As shown in FIG. 3, the electron potential (e.g., the voltage) of the integrated circuit device 108 is highest at the source/drain region 202b. The buffer region 230 provided by the extension segment 226 of the top layer 224 of the hybrid field plate structure 220 enables the electric field in the integrated circuit device 108 to be distributed across additional area above the substrate 106. The greater area of distribution for the electric field increases the breakdown voltage of integrated circuit device 108, which enables the electron potential (e.g., the voltage) of the integrated circuit device 108 to be increased without reaching the breakdown voltage of the integrated circuit device 108.

As indicated above, FIG. 3 is provided as an example. Other examples may differ from what is described with regard to FIG. 3.

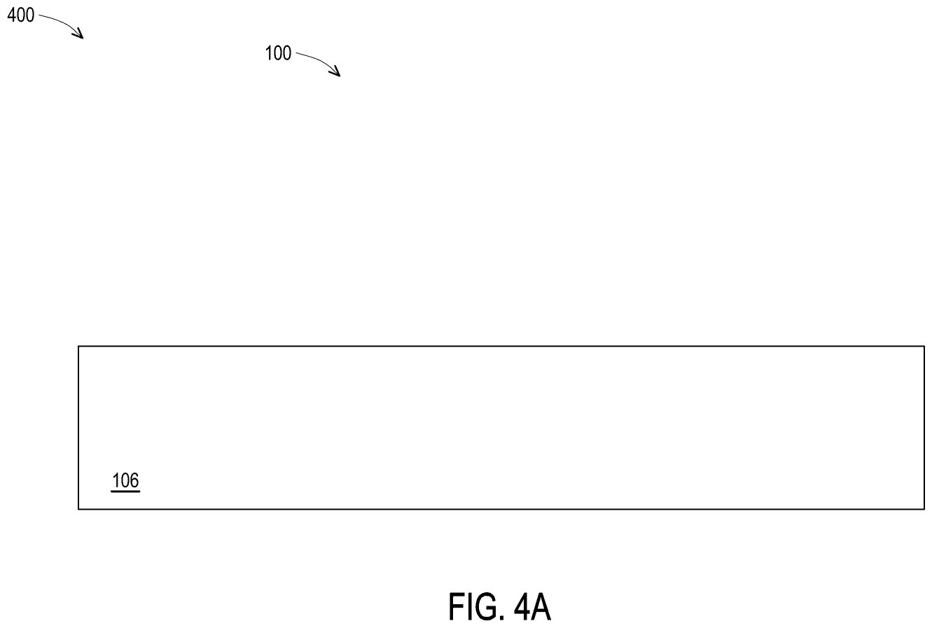

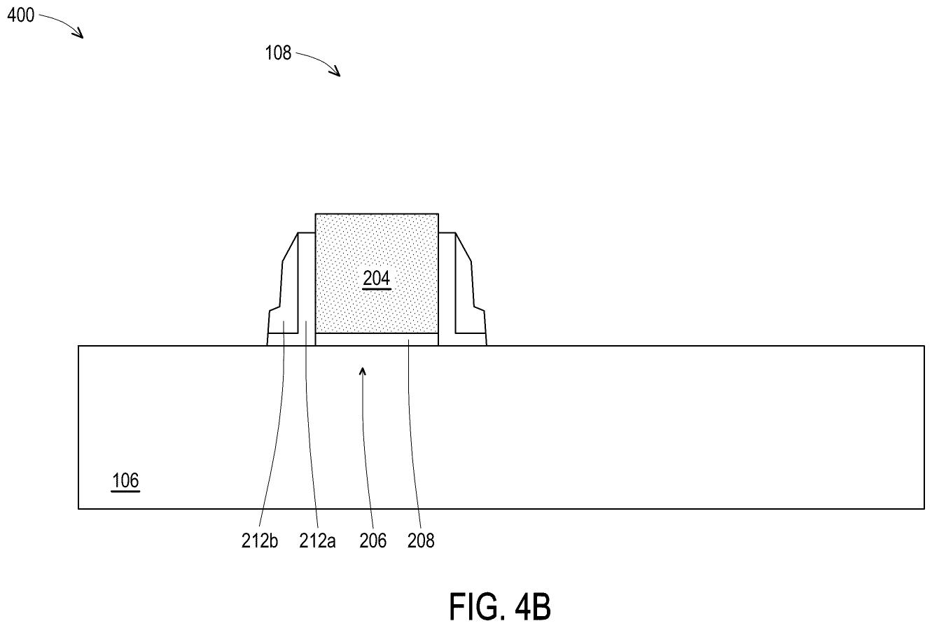

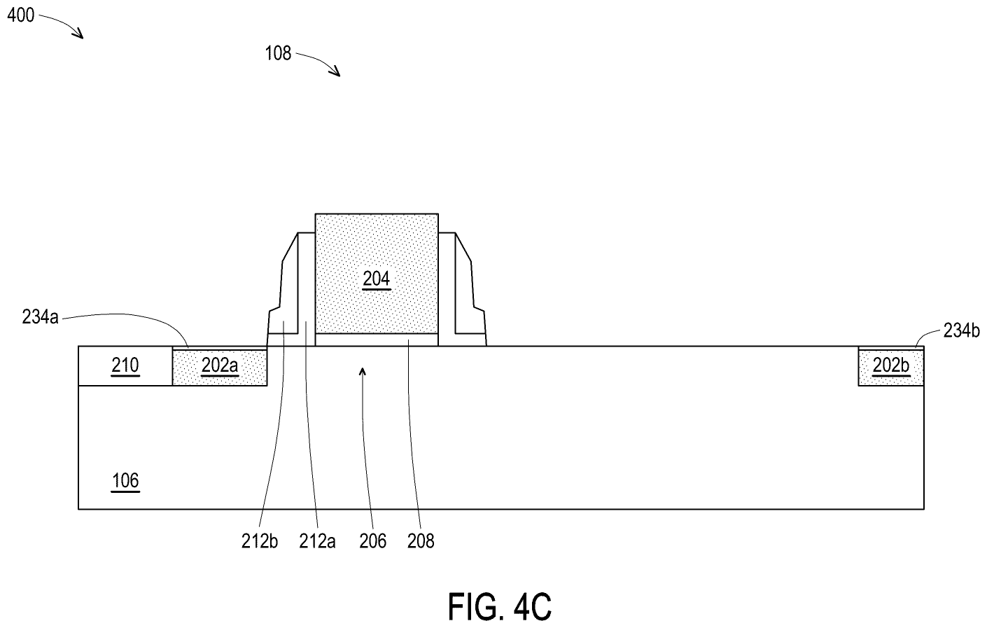

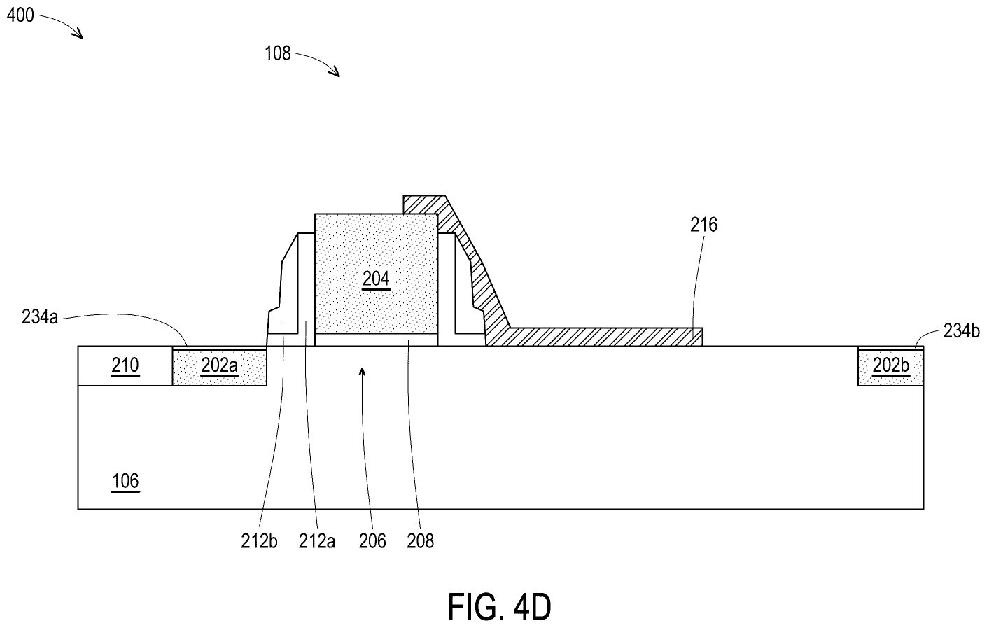

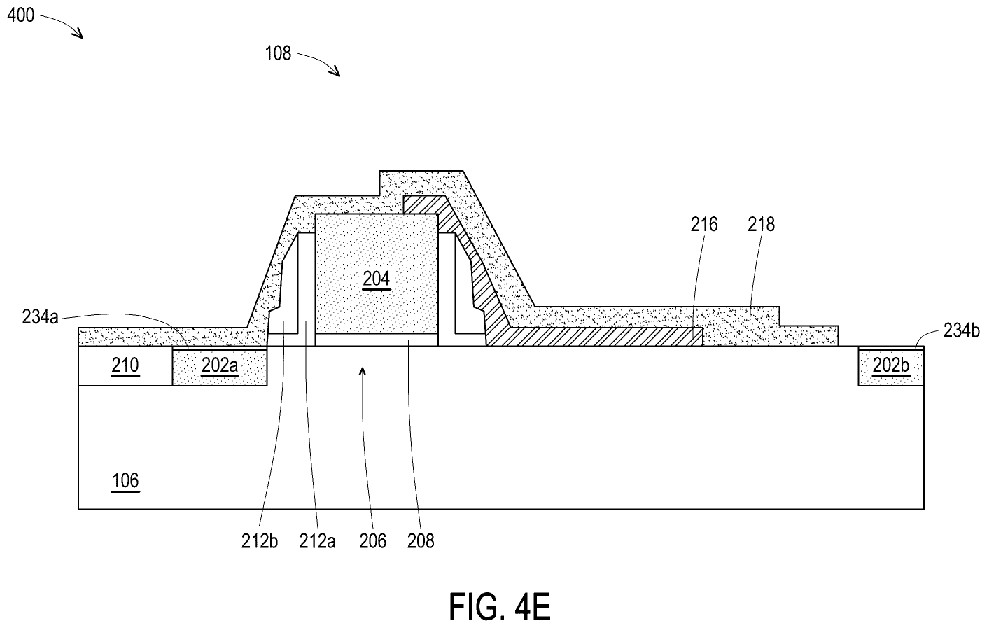

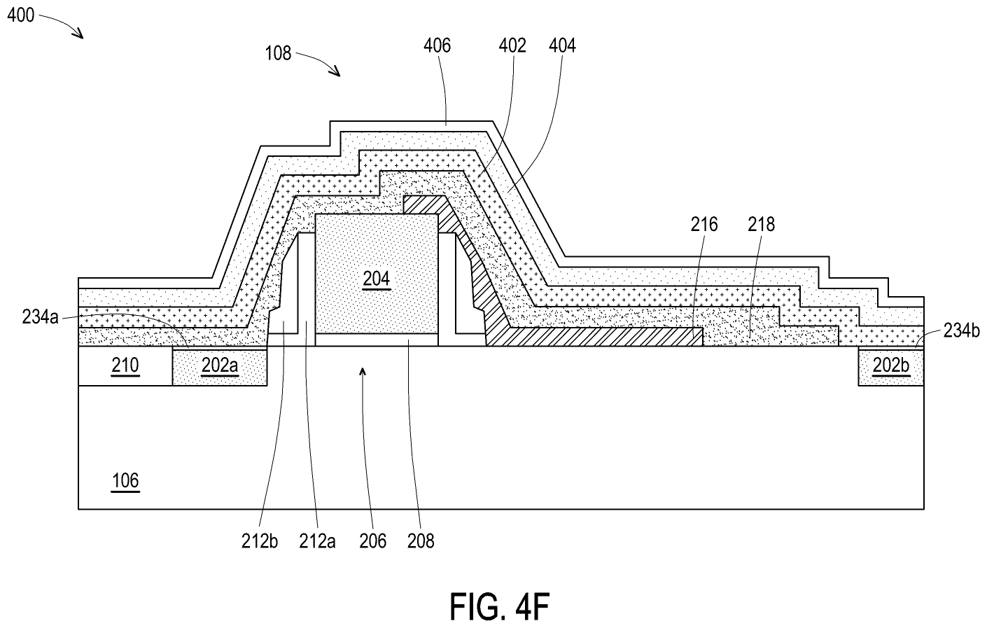

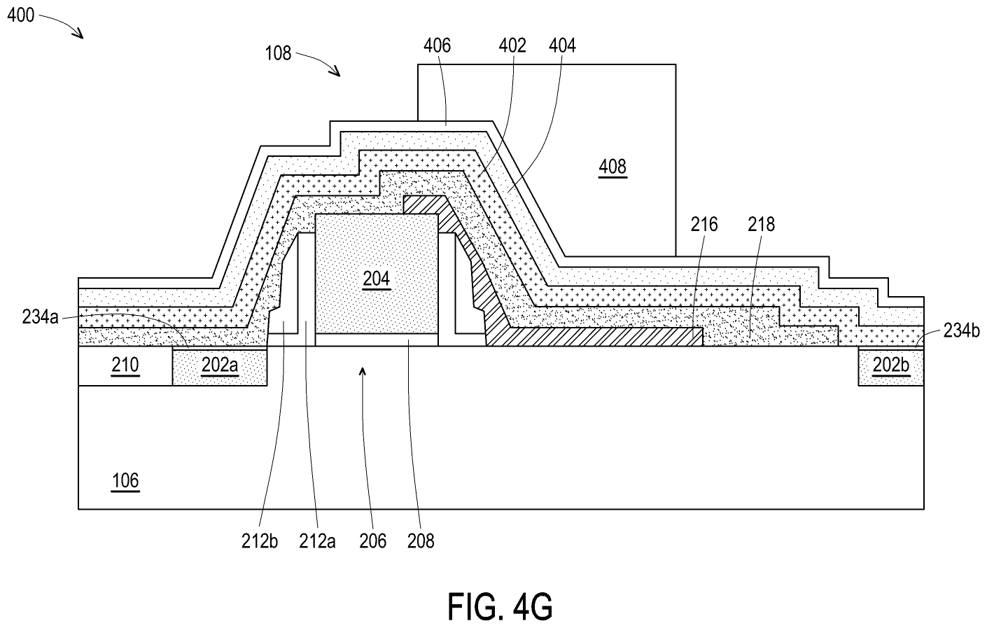

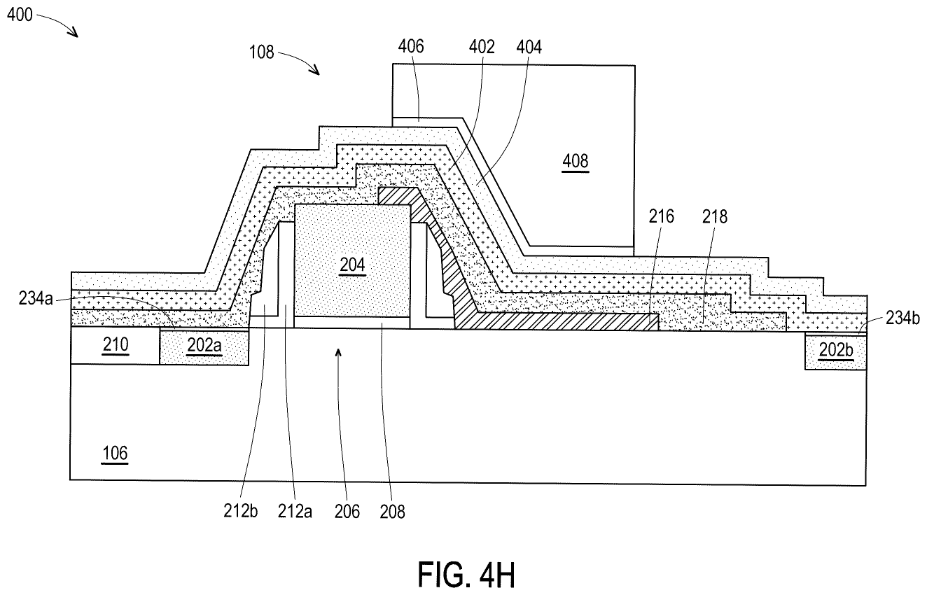

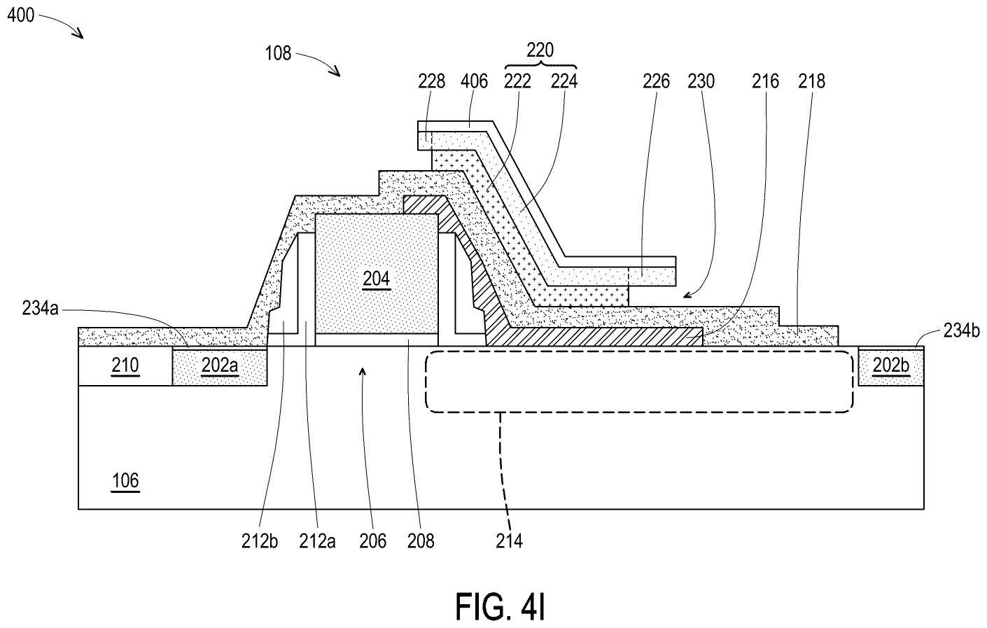

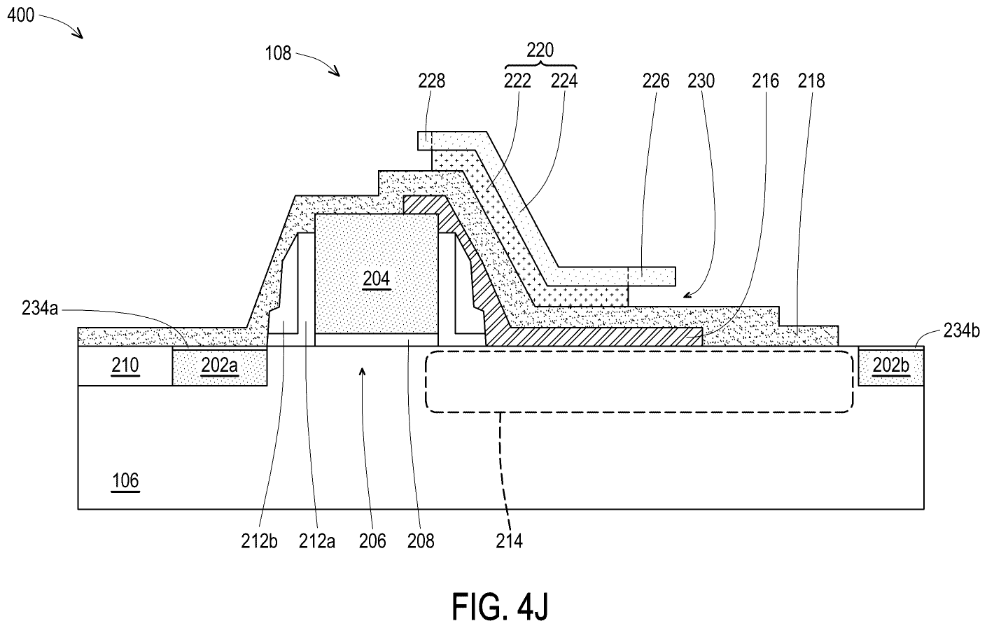

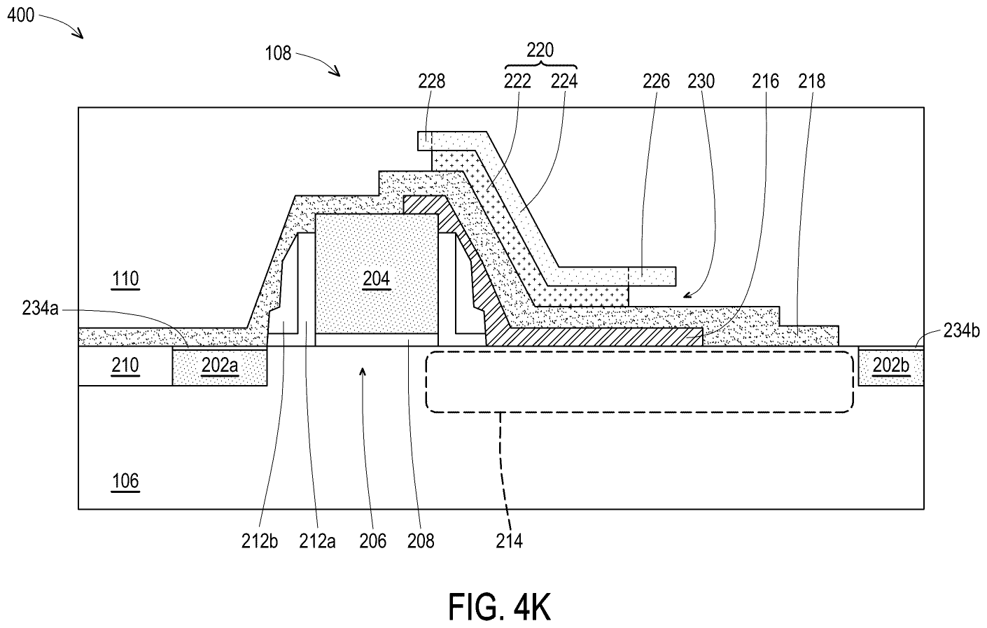

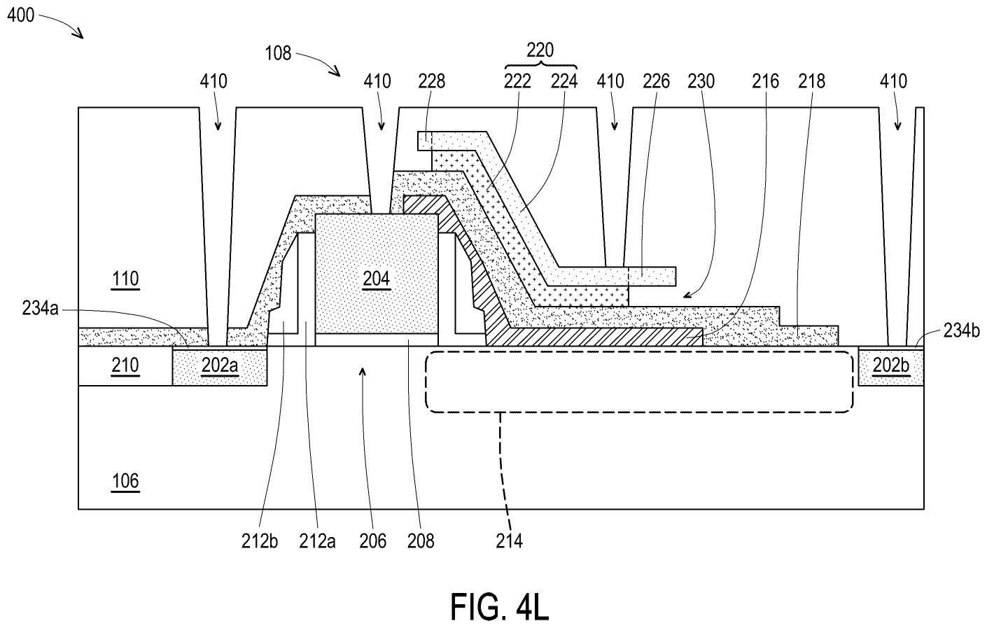

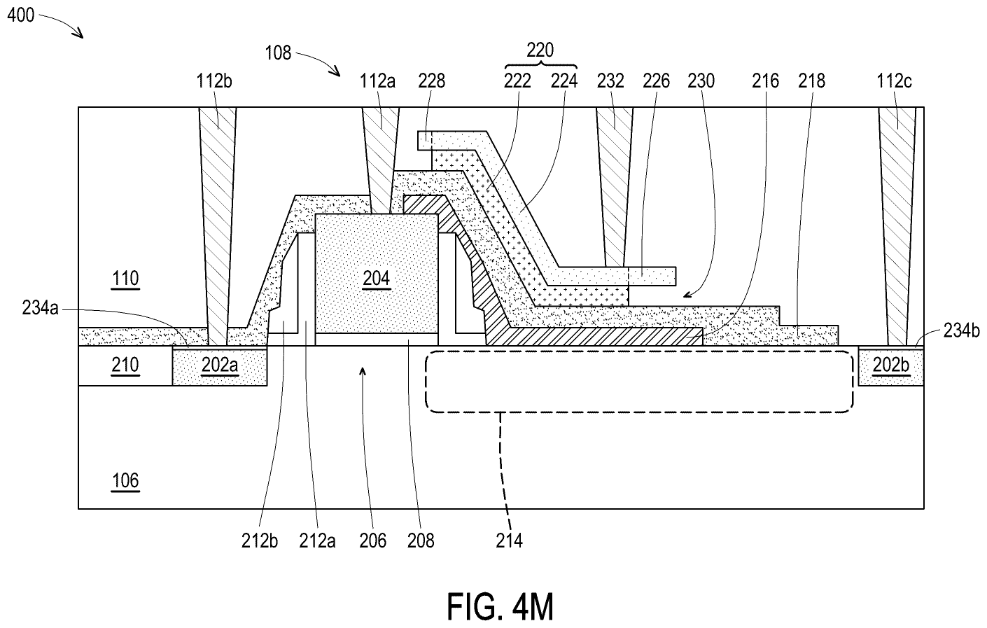

FIGS. 4A-4L are diagrams of an example implementation 400 of forming an integrated circuit device 108 that includes a hybrid field plate structure 220 described herein. In some implementations, one or more of the operations described in connection may be performed using one or more semiconductor processing tools, such as a deposition tool, an exposure tool, a developer tool, an etch tool, an ion implantation tool, a planarization tool, and/or another suitable semiconductor processing tool.

Turning to FIG. 4A, one or more of the operations in the example implementation 400 may be performed in connection with the substrate 106 of the semiconductor device 100. The substrate 106 may be provided in the form of a semiconductor wafer or another type of substrate.

As shown in FIG. 4B, the gate dielectric layer 208 may be formed on the substrate 106. A deposition tool may be used to deposit the gate dielectric layer 208 using a physical vapor deposition (PVD) technique, a chemical vapor deposition (CVD) technique, and atomic layer deposition (ALD) technique, and/or another suitable deposition technique. The gate structure 204 may be formed over and/or on the gate dielectric layer 208. A deposition tool may be used to deposit the gate structure 204 using a PVD technique, a CVD technique, and ALD technique, and electroplating technique, and/or another suitable deposition technique. In some implementations, the gate dielectric layer 208 and the gate structure 204 are deposited and then etched (e.g., using an etch tool) to define the gate dielectric layer 208 and the gate structure 204.

In some implementations, a dummy gate structure is formed in place of the gate structure 204. In these implementations, the dummy gate structure may be removed after formation of source/drain regions of the integrated circuit device 108. This may be referred to as a gate replacement process. The gate structure 204 may be formed in the space left behind after removal of the dummy gate structure.

Sidewall spacer layers (e.g., the seal spacer layers 212a, the bulk spacer layers 212b) may be deposited (e.g., using a deposition tool) using a CVD technique, an ALD technique, a PVD technique, and/or another type of deposition technique. In some implementations, the sidewall spacer layers (e.g., the seal spacer layers 212a, the bulk spacer layers 212b) are deposited on the sidewalls of the gate structure 204. In implementations in which a dummy gate structure is formed as a placeholder for the gate structure 204, the sidewall spacer layers (e.g., the seal spacer layers 212a, the bulk spacer layers 212b) may be formed on the sidewalls of the dummy gate structure. After removal of the dummy gate structure, the gate structure 204 may be deposited in the space between the sidewall spacer layers (e.g., the seal spacer layers 212a, the bulk spacer layers 212b) that was occupied by the dummy gate structure.

As shown in FIG. 4C, one or more isolation regions 210 may be formed in the substrate 106. Forming the one or more isolation regions 210 may include etching (e.g., using an etch tool) the substrate 106 to form one or more recesses in the substrate 106, and using a deposition tool to deposit the one or more isolation regions 210 in the one or more recesses using a CVD technique, an ALD technique, a PVD technique, and/or another type of deposition technique. In some implementations, the isolation region(s) 210 are formed prior to formation of the gate structure 204. In some implementations, the isolation region(s) 210 are formed after formation of the gate structure 204. In some implementations, a planarization tool may be used to perform a chemical-mechanical planarization (CMP) operation to planarize the one or more isolation regions 210 after the one or more isolation regions 210 are deposited.

As further shown in FIG. 4C, the source/drain region 202a and the source/drain region 202b may be formed in the substrate 106. The source/drain region 202a may be formed on a first side of the gate structure 204, and the source/drain region 202b may be formed on a second side of the gate structure 204 opposing the first side. Accordingly, the gate structure 204 is located laterally between the source/drain region 202a and the source/drain region 202b. This enables the gate structure 204 to selectively control the electrical conductivity of a channel region 206 in the substrate 106 between the source/drain region 202a and the source/drain region 202b.

In some implementations, the source/drain region 202a and the source/drain region 202b may be formed by doping portions of the substrate 106. For example, a first portion of the substrate 106 may be doped with one or more types of dopants (e.g., n-type dopants, p-type dopants) to form the source/drain region 202a, and a second portion of the substrate 106 may be doped with one or more types of dopants (e.g., n-type dopants, p-type dopants) to form the source/drain region 202b. An ion implantation tool may be used to implant dopant ions into the first portion and/or into the second portion of the substrate 106 to form the source/drain region 202a and/or the source/drain region 202b. Additionally and/or alternatively, another doping technique may be used to form the source/drain region 202a and the source/drain region 202b such as diffusion.

In some implementations, the source/drain region 202a and the source/drain region 202b are formed by epitaxially growing the source/drain region 202a and the source/drain region 202b in recesses in the substrate 106. An etch tool may be used to etch the substrate 106 to form the recesses in the substrate 106. The etch operation may be referred to a strained source/drain (SSD) etch operation, and the recesses may be referred to as strained source/drain recesses. In some implementations, the etch operation includes a plasma etch technique, a wet chemical etch technique, and/or another type of etch technique.

A deposition tool may be used to form the source/drain region 202a and the source/drain region 202b in the recesses. The deposition tool may be used to form the source/drain region 202a and the source/drain region 202b by epitaxial growth, in which layers of the epitaxial material are deposited in the recesses such that the layers of semiconductor material are formed by epitaxial growth in a particular crystalline orientation.

The material (e.g., silicon (Si), gallium (Ga), or another type of semiconductor material) that is used to form the source/drain region 202a and the source/drain region 202b may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. Examples of n-type dopants that may be used in the epitaxial operation include phosphorous (P) or arsenic (As), among other examples.

As shown in FIG. 4D, the blocking layer 216 may be formed over and/or on a portion of the substrate 106 that is between the gate structure 204 and the source/drain region 202b. The blocking layer 216 may include an angled portion that extends along a sidewall of the gate structure 204. A deposition tool may be used to deposit the blocking layer 216 using a CVD technique, an ALD technique, a PVD technique, and/or another type of deposition technique. In some implementations, blocking layer 216 is deposited as a blanket layer the covers the integrated circuit device 108. An etch tool may be used to subsequently remove portions of the blocking layer 216 over the source/drain region 202a and the source/drain region 202b such that the source/drain region 202a and the source/drain region 202b are exposed through the blocking layer 216. This enables metal silicide layers 234a and 234b to be formed over the source/drain region 202a and the source/drain region 202b without forming the metal silicide layers 234a and 234b on other portions of the substrate 106.

As further shown in FIG. 4D, the metal silicide layers 234a and 234b may be respectively formed on the source/drain regions 202a and 202b. A salicidation process may be performed to form the metal silicide layers 234a and 234b. The salicidation process may include using a deposition tool to deposit a layer of metal material (e.g., titanium (Ti), cobalt (Co), ruthenium (Ru)) on the source/drain regions 202a and 202b, and then performing an annealing operation to cause the metal material to diffuse into the top surface of the source/drain regions 202a and 202b to form the metal silicide layers 234a and 234b. In some implementations, another technique is used to form the metal silicide layers 234a and 234b.

As shown in FIG. 4E, the buffer layer 218 may be formed over the substrate 106. In particular, the buffer layer 218 may be formed over the blocking layer 216, over the gate structure 204, and/or over the source/drain region 202a, among other examples. A deposition tool may be used to deposit the buffer layer 218 using a CVD technique, an ALD technique, a PVD technique, and/or another type of deposition technique.

As shown in FIG. 4F, a first metal-containing layer 402 may be formed over the integrated circuit device 108, and a second metal-containing layer 404 may be formed over the first metal-containing layer 402. A deposition tool may be used to deposit the first metal-containing layer 402 and the second metal-containing layer 404 using a CVD technique, an ALD technique, a PVD technique, an electroplating technique, and/or another type of deposition technique.

As further shown in FIG. 4F, a masking layer 406 may be formed over and/or on the second metal-containing layer 404. The masking layer 406 may include a dielectric material such as a silicon nitride (SiₓN_{y} such as Si₃N₄), an aluminum oxide (AlₓO_{y} such as Al₂O3), silicon oxynitride (SiON), and/or another suitable dielectric material. A deposition tool may be used to deposit the masking layer 406 using a CVD technique, an ALD technique, a PVD technique, and/or another suitable deposition technique.

As shown in FIG. 4G, a photoresist layer 408 may be formed over and/or the second metal-containing layer 404. A deposition tool is used to deposit the photoresist layer 408 using a spin-coating technique and/or another suitable deposition technique.

As further shown in FIG. 4G, the photoresist layer 408 may be patterned such that the photoresist layer 408 remains over a portion of the masking layer 406. An exposure tool may be used to expose the photoresist layer 408 to a radiation source to pattern the photoresist layer 408. A developer tool may be used to develop and remove portions of the photoresist layer 408 to expose the pattern.

As shown in FIG. 4H, a first etch operation may be performed to transfer the pattern from the photoresist layer 408 to the masking layer 406. An etch tool may be used to perform the first etch operation using a wet etching technique. Additionally and/or alternatively, a dry etching technique such as a gas-based etch and/or a plasma-based etch may be used to transfer the pattern from the photoresist layer 408 to the masking layer 406. A photoresist removal tool may be used to remove the remaining portions of the photoresist layer 408 using a chemical stripper, plasma ashing, and/or another technique.

As shown in FIG. 4I, a second etch operation may be performed to etch the first metal-containing layer 402 and the second metal-containing layer 404 based on the pattern in the masking layer 406 to form the hybrid field plate structure 220. An etch tool may be used to perform the second etch operation using a wet etching technique. Additionally and/or alternatively, a dry etching technique such as a gas-based etch and/or a plasma-based etch may be used to etch the first metal-containing layer 402 and the second metal-containing layer 404 based on the pattern in the masking layer 406 to form the hybrid field plate structure 220.

In implementations in which a wet etch technique is used for the second etch operation, an acid-based wet etchant may be used to etch the first metal-containing layer 402 and the second metal-containing layer 404. The acid-based etchant may include a hydrofluoric (HF) acid, a hydrofluoric acid diluted in water, and/or another suitable acid-based etchant.

The etch rate of the wet etchant for the material of the first metal-containing layer 402 may be greater than the etch rate of the wet etchant for the material of the second metal-containing layer 404. This enables the first metal-containing layer 402 to be laterally etched to form the bottom layer 222 and the top layer 224 such that the top layer 224 has extension segments 226 and/or 228 that overhang the bottom layer 222 (e.g., that extend laterally outward from the bottom layer 222) with minimal lateral etching to the top layer 224. For example, the first metal-containing layer 402 may include titanium (Ti), the second metal-containing layer 404 may include titanium nitride (TiN), and the etch rate of the wet etchant for titanium may be greater than the etch rate of the wet etchant for titanium nitride. As another example, the first metal-containing layer 402 may include tantalum (Ta), the second metal-containing layer 404 may include tantalum nitride (TaN), and the etch rate of the wet etchant for tantalum may be greater than the etch rate of the wet etchant for tantalum nitride.

As shown in FIG. 4J, the masking layer 406 may be removed after the hybrid field plate structure 220 is formed. In some implementations, a photoresist removal tool is used to remove the remaining portions of the masking layer 406 using a chemical stripper, plasma ashing, and/or another technique. In some implementations, the masking layer 406 is removed by etching.

As shown in FIG. 4K, the dielectric layer 110 may be formed over and/or on the integrated circuit device 108 after the hybrid field plate structure 220 is formed. Material of the dielectric layer 110 may fill in the areas under the extension segments 226 and 228 of the top layer 224 of the hybrid field plate structure 220, resulting in formation of the buffer region 230 under the extension segment 226. A deposition tool may be used to deposit the dielectric layer 110 using a PVD technique, a CVD technique, an ALD technique, an oxidation technique, and/or another suitable deposition technique. In some implementations, a planarization tool is used to perform a CMP operation to planarize the dielectric layer 110.

As shown in FIG. 4L, recesses 410 may be formed through the dielectric layer 110. For example, a recess 410 may be formed over the source/drain region 202a to expose the metal silicide layer 234a on the source/drain region 202a through the recess 410. As another example, a recess 410 may be formed over the source/drain region 202b to expose the metal silicide layer 234b on the source/drain region 202b through the recess 410. As another example, a recess 410 may be formed over the gate structure 204 to expose the gate structure 204 through the recess 410. As another example, a recess 410 may be formed over the hybrid field plate structure 220 to expose the top layer 224 of the hybrid field plate structure 220 through the recess 410.

In some implementations, a pattern in a photoresist layer is used to form the recesses 410. In these implementations, a deposition tool may be used to form the photoresist layer over the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 110 to form the recesses 410. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 410 based on a pattern.

As shown in FIG. 4M, the contact structure 112a (e.g., a gate contact) may be formed in the recess 410 over the gate structure 204 such that the contact structure 112a lands on the gate structure 204. The contact structure 112b (e.g., a source/drain contact) may be formed in the recess 410 over the source/drain region 202a such that the contact structure 112b lands on the metal silicide layer 234a on the source/drain region 202a. The contact structure 112c (e.g., a source/drain contact) may be formed in the recess 410 over the source/drain region 202b such that the contact structure 112c lands on the metal silicide layer 234b on the source/drain region 202b. The field plate contact 232 may be formed in the recess 410 over the hybrid field plate structure 220 such that the field plate contact 232 lands on the top layer 224 of the hybrid field plate structure 220. In some implementations, the field plate contact 232 lands on the extension segment 226 of the top layer 224 of the hybrid field plate structure 220.

A deposition tool may be used to deposit the contact structures 112a-112c and the field plate contact 232 using a CVD technique, a PVD technique, an ALD technique, an electroplating technique, and/or another suitable deposition technique. The contact structures 112a-112c and the field plate contact 232 may be deposited in one or more deposition operations. In some implementations, a seed layer is first deposited, and the contact structures 112a-112c and the field plate contact 232 are deposited on the seed layer. In some implementations, a liner is deposited in the recesses 410, and the contact structures 112a-112c and the field plate contact 232 are deposited on the liner in the recesses 410. The liner may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the contact structures 112a-112c and the field plate contact 232 after the contact structures 112a-112c and the field plate contact 232 are deposited.

As indicated above, FIGS. 4A-4M is provided as an example. Other examples may differ from what is described with regard to FIGS. 4A-4M.

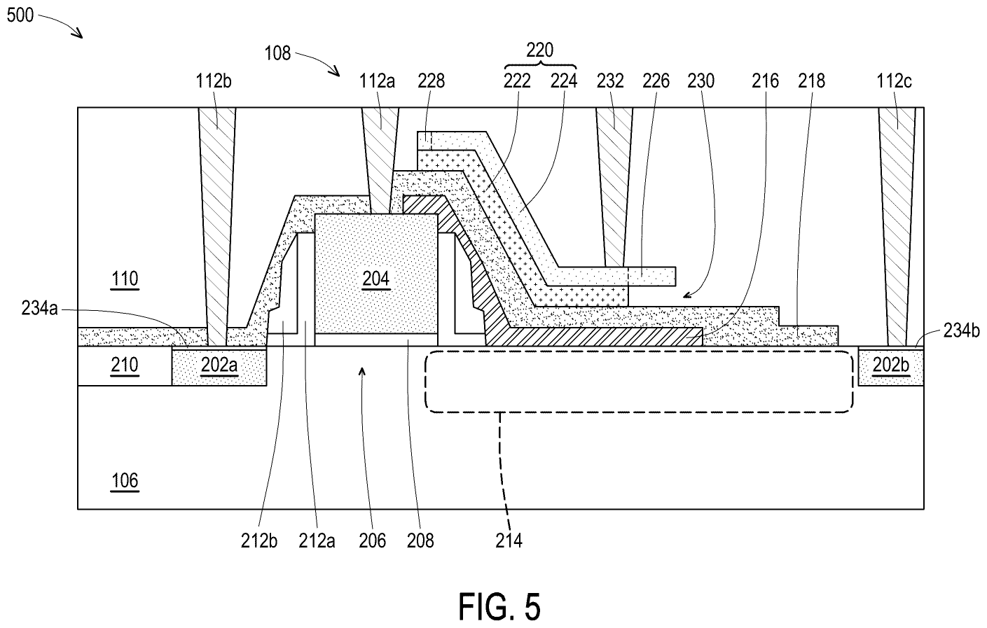

FIG. 5 is a diagram of an example implementation 500 of an integrated circuit device 108 described herein. In the example implementation 500, the integrated circuit device 108 includes a similar combination and arrangement of layers and structures as the example implementation 200 of the integrated circuit device 108 in FIG. 2. However, as shown in FIG. 5, the example implementation 500 of the integrated circuit device 108 includes only the extension segment 226 that extends laterally outward past the end of the bottom layer 222 of the hybrid field plate structure 220 facing the source/drain region 202b.

In some implementations, the extension segment 228 may be omitted by performing a first etch operation (e.g., a plasma-based etch) in which a highly directional/vertical etch is performed to etch the first metal-containing layer 402 and the second metal-containing layer 404 based on the pattern in the masking layer 406 to form the bottom layer 222 and the top layer 224 of the hybrid field plate structure 220. Another masking layer may be formed such that the masking layer covers the ends of the bottom layer 222 and the top layer 224 that are over the gate structure 204, and then performing a second etch (e.g., a wet etch) to etch the end of the bottom layer 222 facing the source/drain region 202b to form the extension segment 226 of the top layer 224. Alternatively, the bottom layer 222 may be formed, a spacer layer may be formed around the bottom layer 222, and then the top layer 224 may be formed on the bottom layer 222 and etched such that the extension segment 226 extends over a portion of the spacer layer adjacent to the bottom layer 222.

As indicated above, FIG. 5 is provided as an example. Other examples may differ from what is described with regard to FIG. 5.

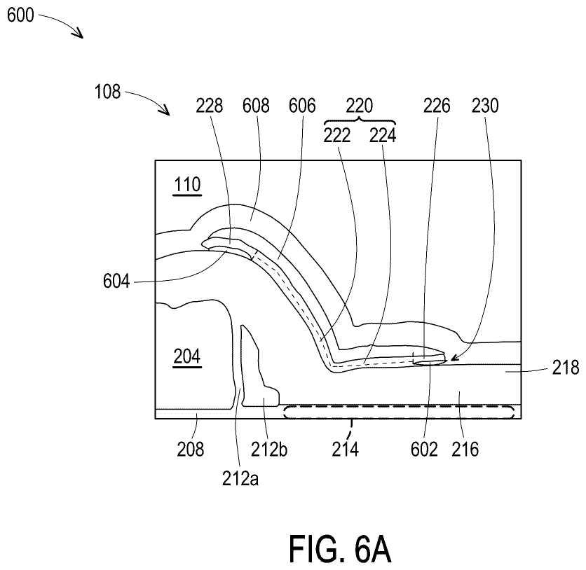

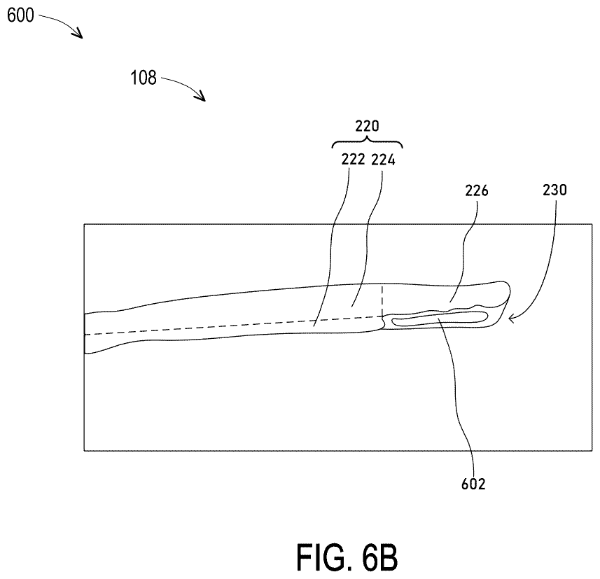

FIGS. 6A and 6B are diagrams of an example implementation 600 of an integrated circuit device 108 described herein. In the example implementation 600, the integrated circuit device 108 includes a similar combination and arrangement of layers and structures as the example implementation 200 of the integrated circuit device 108 in FIG. 2. However, as shown in FIGS. 6A and 6B, the example implementation 600 of the integrated circuit device 108 includes air gaps 602 and/or 604 under the extension segments 226 and/or 228, respectively. Thus, the buffer region 230 under the extension segment 226 may include the air gap 602.

The air gaps 602 and/or 604 may provide dielectric regions in which the dielectric constant is approximately 1 (one) (e.g., the dielectric constant of air). The air gaps 602 and/or 604 may be formed due to the areas under the extension segments 226 and/or 228 not being fully filled in with dielectric material when forming dielectric layers over the integrated circuit device 108. The areas under the extension segments 226 and/or 228 may be closed up before being fully filled in with dielectric material when forming dielectric layers over the integrated circuit device 108.

As further shown in FIG. 6A, an additional dielectric layer may be included over and/or on the integrated circuit device 108. For example, a capping layer 606 may be formed on the top layer 224 of the hybrid field plate structure 220. As another example, a capping layer 608 may be formed over and/or on the gate structure 204, the hybrid field plate structure 220, and/or the buffer layer 218.

As shown in a closeup view of the buffer region 230 in FIG. 6B, the buffer region 230 may be partially composed of dielectric material. The remaining area in the buffer region 230 may be occupied by the air gap 602 (e.g., which may correspond to the unfilled area of the buffer region 230). In some implementations, the dielectric material may be filled in at the bottom of the buffer region 230 (e.g., on the buffer layer 218) toward the open end of the buffer region 230, and may taper off further into the buffer region 230.

As indicated above, FIGS. 6A and 6B are provided as an example. Other examples may differ from what is described with regard to FIGS. 6A and 6B.

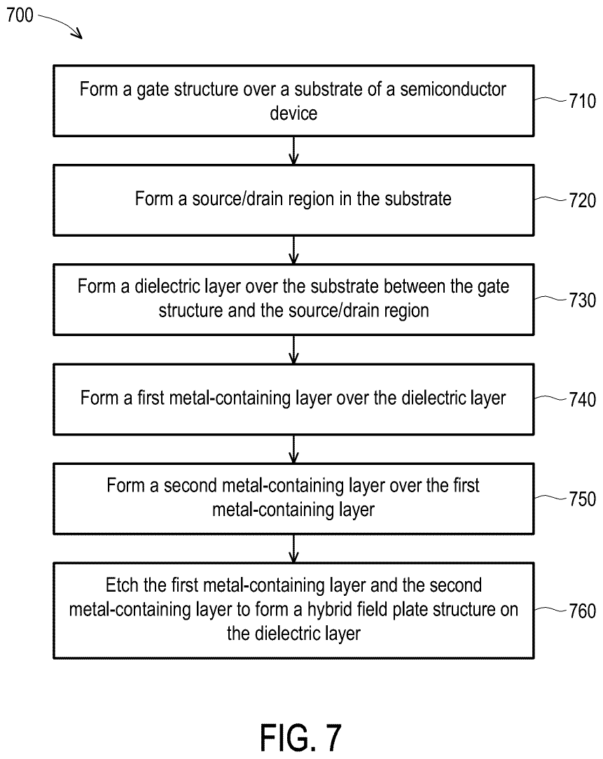

FIG. 7 is a flowchart of an example process 700 associated with forming an integrated circuit device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a gate structure over a substrate of a semiconductor device (block 710). For example, one or more semiconductor processing tools may be used to form a gate structure (e.g., a gate structure 204 of an integrated circuit device 108) over a substrate (e.g., a substrate 106) of a semiconductor device (e.g., a semiconductor device 100), as described herein.

As further shown in FIG. 7, process 700 may include forming a source/drain region in the substrate (block 720). For example, one or more semiconductor processing tools may be used to form a source/drain region (e.g., a source/drain region 202a of the integrated circuit device 108) in the substrate, as described herein.

As further shown in FIG. 7, process 700 may include forming a dielectric layer over the substrate between the gate structure and the source/drain region (block 730). For example, one or more semiconductor processing tools may be used to form a dielectric layer (e.g., a blocking layer 216, a buffer layer 218) over the substrate between the gate structure and the source/drain region, as described herein.

As further shown in FIG. 7, process 700 may include forming a first metal-containing layer over the dielectric layer (block 740). For example, one or more semiconductor processing tools may be used to form a first metal-containing layer (e.g., a first metal-containing layer 402) over the dielectric layer, as described herein.

As further shown in FIG. 7, process 700 may include forming a second metal-containing layer over the first metal-containing layer (block 750). For example, one or more semiconductor processing tools may be used to form a second metal-containing layer (e.g., a second metal-containing layer 404) over the first metal-containing layer, as described herein.

As further shown in FIG. 7, process 700 may include etching the first metal-containing layer and the second metal-containing layer to form a hybrid field plate structure on the dielectric layer (block 760). For example, one or more semiconductor processing tools may be used to etch the first metal-containing layer and the second metal-containing layer to form a hybrid field plate structure (e.g., a hybrid field plate structure 220) on the dielectric layer, as described herein.

Process 700 may include additional implementations, such as any single implementation or any combination of implementations described below and/or in connection with one or more other processes described elsewhere herein.

In a first implementation, etching the first metal-containing layer and the second metal-containing layer includes performing a wet etch operation using a wet etchant, where a first etch rate of the wet etchant for the first metal-containing layer is different from a second etch rate of the wet etchant for the second metal-containing layer.

In a second implementation, alone or in combination with the first implementation, the first etch rate of the wet etchant for the first metal-containing layer is greater than the second etch rate of the wet etchant for the second metal-containing layer.

In a third implementation, alone or in combination with one or more of the first and second implementations, the first etch rate of the wet etchant for the first metal-containing layer being greater than the second etch rate of the wet etchant for the second metal-containing layer results in formation of an extension segment (e.g., an extension segment 226) of a top layer (e.g., a top layer 224) of the hybrid field plate structure that laterally extends outward past an end of a bottom layer (e.g., a bottom layer 222) of the hybrid field plate structure.

In a fourth implementation, alone or in combination with one or more of the first through third implementations, process 700 includes filling in an area under the extension segment with dielectric material to form a buffer region (e.g., a buffer region 230).

In a fifth implementation, alone or in combination with one or more of the first through fourth implementations, forming the second dielectric layer includes depositing material of the second dielectric layer such that an air gap (e.g., an airgap 602) is formed in an area under the extension segment.

In a sixth implementation, alone or in combination with one or more of the first through fifth implementations, etching the first metal-containing layer and the second metal-containing layer includes forming a masking layer (e.g., a masking layer 406) over a portion of the second metal-containing layer, and etching the first metal-containing layer and the second metal-containing layer based on a pattern in the masking layer to form a hybrid field plate structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a high-voltage transistor includes a hybrid field plate structure in a channel region of the high-voltage transistor that is between a gate structure and a source/drain region of the high-voltage transistor. The hybrid field plate structure includes a multiple-layer structure in which a plurality of layers (e.g., a bottom layer and a top layer, among other examples) that contain different materials are stacked above the channel region. The different materials of the layers of the hybrid field plate structure enable the bottom layer to be etched at a faster etch rate than the top layer. The faster etch rate enables the ends of the bottom layer to be etched such that the ends of the top layer overhang laterally outward past the bottom layer. This overhang creates a buffer region under the ends of the top layer. The buffer region under the ends of the top layer of the hybrid field plate structure provides for further electric field distribution in that the buffer region provides additional area across which the electric field can be distributed for further reduction in the peak electric field magnitude of the electric field. Thus, the buffer region increases the performance of the high-voltage transistor with minimal to no increase in lateral footprint of the high-voltage transistor.

As described in greater detail above, some implementations described herein provide a semiconductor device. The semiconductor device includes a first source/drain region in a substrate. The semiconductor device includes a second source/drain region in the substrate. The semiconductor device includes a gate structure over the substrate and between the first source/drain region and the second source/drain region. The semiconductor device includes a dielectric layer over the substrate and between the gate structure and the second source/drain region. The semiconductor device includes a hybrid field plate structure that extends along a portion of the dielectric layer. The hybrid field plate structure includes a first layer on the dielectric layer and a second layer on the first layer. The first layer includes a first material, and the second layer includes a second material that is different from the first material.

As described in greater detail above, some implementations described herein provide a method. The method includes forming a gate structure over a substrate of a semiconductor device. The method includes forming a first source/drain region in the substrate, where the first source/drain region is on a first side of the gate structure. The method includes forming a second source/drain region in the substrate, where the second source/drain region is on a second side of the gate structure opposing the first side. The method includes forming a first dielectric layer over the substrate between the gate structure and the second source/drain region. The method includes forming a first metal-containing layer over the first dielectric layer. The method includes forming a second metal-containing layer over the first metal-containing layer. The method includes forming a masking layer over a portion of the second metal-containing layer. The method includes etching the first metal-containing layer and the second metal-containing layer based on the masking layer to form a hybrid field plate structure on the first dielectric layer. The method includes removing the masking layer after forming the hybrid field plate structure. The method includes forming a second dielectric layer on the hybrid field plate structure.

As described in greater detail above, some implementations described herein provide a semiconductor device. The semiconductor device includes a first source/drain region in a substrate. The semiconductor device includes a second source/drain region in the substrate. The semiconductor device includes a gate structure over the substrate and between the first source/drain region and the second source/drain region. The semiconductor device includes a dielectric layer over the substrate and between the gate structure and the second source/drain region. The semiconductor device includes a multiple-layer field plate structure that extends along a portion of the dielectric layer. The multiple-layer field plate structure includes a first layer on the dielectric layer and a second layer on the first layer. A first end of the first layer facing the second source/drain region is further away from the second source/drain region than a second end of the second layer facing the second source/drain region.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region in a substrate;
a second source/drain region in the substrate;
a gate structure over the substrate and between the first source/drain region and the second source/drain region;
a dielectric layer over the substrate and between the gate structure and the second source/drain region; and
a hybrid field plate structure that extends along a portion of the dielectric layer,
wherein the hybrid field plate structure comprises:
a first layer, on the dielectric layer, comprising a first material; and
a second layer, on the first layer, comprising a second material that is different from the first material.

2. The semiconductor device of claim 1, wherein the first layer comprises a metal material; and
wherein the second layer comprises a metal nitride material.

3. The semiconductor device of claim 2, wherein the metal nitride material contains a nitride of the metal material of the first layer.

4. The semiconductor device of claim 1, wherein the second layer comprises an extension segment that extends laterally outward past an end of the first layer.

5. The semiconductor device of claim 4, wherein the extension segment extends laterally toward the second source/drain region.

6. The semiconductor device of claim 4, wherein the second layer further comprises another extension segment that extends laterally outward past another end of the first layer facing the gate structure.

7. The semiconductor device of claim 6, wherein the other extension segment extends over a portion of the gate structure.

8. A method, comprising:
forming a gate structure over a substrate of a semiconductor device;
forming a source/drain region in the substrate;
forming a dielectric layer over the substrate between the gate structure and the source/drain region;
forming a first metal-containing layer over the dielectric layer;
forming a second metal-containing layer over the first metal-containing layer; and
etching the first metal-containing layer and the second metal-containing layer to form a hybrid field plate structure on the dielectric layer.

9. The method of claim 8, wherein etching the first metal-containing layer and the second metal-containing layer comprises:
performing a wet etch operation using a wet etchant,
wherein a first etch rate of the wet etchant for the first metal-containing layer is different from a second etch rate of the wet etchant for the second metal-containing layer.

10. The method of claim 9, wherein the first etch rate of the wet etchant for the first metal-containing layer is greater than the second etch rate of the wet etchant for the second metal-containing layer.

11. The method of claim 10, wherein the first etch rate of the wet etchant for the first metal-containing layer being greater than the second etch rate of the wet etchant for the second metal-containing layer results in formation of an extension segment of a top layer of the hybrid field plate structure that laterally extends outward past an end of a bottom layer of the hybrid field plate structure.

12. The method of claim 11, further comprising:
filling in an area under the extension segment with dielectric material to form a buffer region.

13. The method of claim 12, further comprising:
forming another dielectric layer over the hybrid field plate structure such that an air gap is formed in the area under the extension segment.

14. The method of claim 8, wherein etching the first metal-containing layer and the second metal-containing layer comprises:
forming a masking layer over a portion of the second metal-containing layer; and
etching the first metal-containing layer and the second metal-containing layer based on a pattern in the masking layer to form the a hybrid field plate structure.

15. A semiconductor device, comprising:
a first source/drain region in a substrate;
a second source/drain region in the substrate;
a gate structure over the substrate and between the first source/drain region and the second source/drain region;
a dielectric layer over the substrate and between the gate structure and the second source/drain region; and
a multiple-layer field plate structure that extends along a portion of the dielectric layer,
wherein the multiple-layer field plate structure comprises:
a first layer, on the dielectric layer; and
a second layer on the first layer,
wherein a first end, of the first layer, facing the second source/drain region is further away from the second source/drain region than a second end, of the second layer, facing the second source/drain region.

16. The semiconductor device of claim 15, further comprising:
a dielectric buffer region vertically between the dielectric layer and the second layer of the multiple-layer field plate structure.

17. The semiconductor device of claim 16, wherein the dielectric buffer region is laterally adjacent to the first end of the first layer of the multiple-layer field plate structure.

18. The semiconductor device of claim 15, further comprising:
an air gap vertically between the dielectric layer and the second layer of the multiple-layer field plate structure.

19. The semiconductor device of claim 15, wherein a third end, of the first layer, facing the gate structure is further away from the gate structure than a fourth end, of the second layer, facing the gate structure.

20. The semiconductor device of claim 19, further comprising:
an air gap under the second layer and adjacent to the third end of the first layer.
